(19) United States
(12) Patent Application Publication
(10) Pub. No.: US 2006/0208754 A1
(43) Pub. Date: Sep. 21, 2006

(54) Method and apparatus for a reliability testing

(75) Inventors: Yasuhiro Takeuchi, Tokyo (JP); Hiroshi Nada, Tokyo (JP)

Correspondence Address: Paul D. Greeley;Ohlandt, Greeley, Ruggiero & Perle, L.L.P., 10th Floor, One Landmark Square, Stamford, CT, 06901-2682, US

(73) Assignee: Agilent Technologies, Inc.

(21) Appl. No.: 11/317,511

(22) Filed: Dec. 22, 2005

(30) Foreign Application Priority Data
Mar. 18, 2005 (JP) 2005-078529

(51) Int. Cl. G01R 31/26

(52) U.S. Cl. 324/765

(57) ABSTRACT

A method for a reliability testing of a device under test which comprises: a first step for applying a second voltage after applying for a predetermined time a first voltage to a device under test and measuring the current flowing through the device under test; a second step for conducting the first step on the same device under test two or more consecutive times; a third step for conducting in succession the second step on a plurality of devices under test; a fourth step for conducting the first step on the same device under test, once or two or more consecutive times; a fifth step for conducting in succession the fourth step on a plurality of devices under test after conducting the third step; and a sixth step for finding the relationship between the total time for which the first voltage has been applied and the current for each device under test, and an apparatus that uses this method.

### FIELD OF THE INVENTION

The present invention relates to a method and an apparatus for a reliability testing of semiconductor devices, and in particular, to a method and an apparatus for a reliability testing that uses the TDDB (Time-Dependent Dielectric Breakdown) test.

### DISCUSSION OF THE BACKGROUND ART

The TDDB test described in ] JP Unexamined Patent Application (Kokai) 5[1993]-308,094 is a reliability testing method for evaluating the service life of a semiconductor device. The TDDB test is a testing method that uses the time-dependent breakdown phenomenon whereby when a voltage that is the breakdown voltage or lower is applied for a long period of time to an MOS Gate oxide film (dielectric thin film), the gate oxide film breaks down dependent on this application time. That is, the TDDB test is a test whereby a stress voltage, which is the breakdown voltage or lower, but higher than the voltage normally used, is continuously applied to the gate oxide film of a semiconductor device for testing, and the reliability of the gate insulation film is tested based on the extent to which breakdown of the gate oxide film proceeds. The current flowing through the oxide film gradually increases when the gate oxide film breaks down. The TDDB test is a method for reliability testing that involves measuring the total time for which the stress voltage is applied until this current reaches a predetermined current that serves as an indicator for assessing service life and estimating the service life of the device under conditions of normal usage.

The recent progress in semiconductor technology has led to dramatic improvement of device reliability. Therefore, a stress voltage must be applied and the current must be monitored over a very long period of time until the current that serves as an indicator of malfunction is reached. Consequently, the method is generally used whereby the total time for which the stress voltage has been applied when the current at which there is malfunction (malfunction generation time) is estimated from the relationship between the total time for which the stress voltage is applied and changes in current without actually monitoring the device until the current at which malfunction occurs is reached.

FIG. 11 shows a diagram of the structure of a conventional apparatus 410 for reliability testing. Apparatus 410 for reliability testing comprises two power sources 11 and 12; an ammeter 13 connected in series to power source 12; connection terminals 51, 52, and 53 for connecting devices under test 31, 32, and 33; a multiplexer 20 for selectively connecting the output of power sources 11 and 12 to connection terminals 51, 52, and 53; and a control device 440 for controlling the operation of power sources 11 and 12, ammeter 13, and multiplexer 20. Apparatus 410 for reliability testing has 100 connection terminals and is capable of conducting parallel reliability testing of 100 semiconductor devices. By increasing the number of connection terminals 51, 52, 53, and so forth and the number of switches 21, 22, 23, and so forth, the number of devices on which parallel testing can be conducted can be increased and the testing cost can be reduced in accordance with this increase.

Power sources 11 and 12 are variable voltage power sources and the output voltage is controlled by control device 440. Multiplexer 20 comprises switches 21, 22, and 23, which are disposed for each connection terminal 51, 52, and 53. Each connection terminal 51, 52, and 53 can be switched between the three states of being electrically connected to power source 11, electrically connected to power source 12, and not electrically connected to either power source by switching switches 21, 22, and 23. The phrase “electrically connected” here includes not only the case where two components are directly connected by a circuit pattern or wiring, but also the case whereby electricity is being conducted through switches, resistors, and the like. Apparatus 410 for reliability testing has 100 connection terminals and therefore, multiplexer 20 has 100 switches. Control device 440 has a memory 442 and a microprocessor (MPU) 441, which is a data processing means. A computer can be used. It should be noted that apparatus 410 for reliability testing has one power source 12 to which ammeter 13 is connected. Therefore, switches 21, 22, and 23 are three-pole switches. However, when there are multiple sets of combinations of ammeters and power sources possible, the switches will have the number of sets +2 poles.

Next, the conventional method for reliability testing will be described based on the operation flow chart in FIG. 2 and the timing chart in FIG. 3 using apparatus 410 for reliability testing. The timing chart of the present application represents the time for measuring the current by ammeter 13 and the time needed for the operations that accompany measurement, including switching of multiplexer 20 and writing the measurement results in memory 22, as “testing.” When reliability testing is started, a variable c, which indicates the number of times a first device under test is tested, and a variable n, which shows the No. of the device currently being tested, are initialized at 1 (step 100). In this case, all of switches 21, 22, 23, and so forth of multiplexer 20 are set so that they are not connected to either power source 11 or power source 12. Moreover, the output voltage of both power source 11 and power source 12 is set at a stress voltage.

Testing of the connected device is then initiated. First, multiplexer 20 is controlled, switch 21 is switched, and a first device under test 31 is electrically connected to ammeter 13 (step 101). In addition, the current flowing from power source 12 to device 31 is measured by ammeter 13 and the current (initial) is stored in memory 442 (step 102). Once the current is measured, switch 21 is switched and connection terminal 51 is connected to power source 11 (step 103). The measurement of the initial value of device under test 31 is completed.

Variable n is then increased (step 104), and the initial current of the next device under test 32 is measured. The initial value of 100 devices is measured in succession in this way (step 105). The measurement of the current of each device is accompanied by the switching operation of switch 21; therefore, each test takes at least one second. Consequently, it takes 100 seconds to measure the initial current of all 100 devices. Next, variable c is increased, the value of variable n is initialized at 1 (step 106), and the second test is performed in succession beginning with first device under test 31. The stress voltage is applied by voltage source 11 to device 31 from the time the initial value is measured up to the second test; therefore, the current of device 31 that is obtained with the second test is the current when the stress voltage has been applied for 100 seconds. The measured current and the time for which the stress voltage has been applied during the tests are stored for each device under test in memory 442 beginning with the second test.

In this way, 3,000 tests are repeated for each device under test (step 107). Once the tests are completed, the formula is found for the relationship between the time for which the stress voltage is applied and the current is found for each device (step 108). The relationship varies with the type of device, but it is generally approximated by a linear function, a higher-order function, an exponential function, and the like, with the x-axis serving as the time axis on a logarithmic scale. FIG. 4 shows the relationship between the test results for device under test 31 and the approximation formula. A typical four-point plot is shown in the figure, but the approximation formula is actually found based on the results of 3,000 tests.

Next, the malfunction generation time is estimated from the resulting approximate formula (step 109). The current that serves as the indicator of a malfunction is pre-specified taking into consideration the extent of breakdown in the gate oxide film; therefore, the time for which the stress voltage is applied until there is a malfunction (malfunction generation time) is estimated by using the approximate formula to calculate backwards the application time when the current in question is obtained. In the case of device under test 31, it is estimated that a malfunction will occur when the stress voltage has been applied for 10¹⁰ seconds, as in FIG. 4. The estimated malfunction generation time is the result of measuring the current while applying a stress voltage that is higher than the voltage under which the device is normally used. Therefore, the service life of semiconductor devices 31, 32, 33, and so forth is estimated by conversion to the service life when used under the voltage that is normally used (step 110). The above-mentioned estimation of service life is conducted for each device under test and the reliability testing is completed.

By means of the conventional method for reliability testing, the first measurement of current after the application of the stress voltage is performed after 100 seconds of stress voltage application, as shown in FIG. 4. Therefore, the results of measuring the current are distributed between 10² and 10⁵ seconds. Consequently, by means of the conventional method for reliability testing, the approximate formula is found from this distribution range and the estimate of service life is as much as 10¹⁰ seconds. That is, the approximate formula is found from narrowly focused test results and the estimate is of a point that greatly exceeds this range. Therefore, test precision is poor with devices that fluctuate considerably and it is difficult to test their reliability with stable precision.

### SUMMARY OF THE INVENTION

The above-mentioned problem is solved by a method for the reliability testing of a device under test, characterized in that it comprises a first step for applying a second voltage after applying for a predetermined time a first voltage to a device under test and measuring the current flowing through the device under test; a second step for conducting the first step on the same device under test two or more consecutive times; a third step for conducting in succession the second step on a plurality of devices under test; a fourth step for conducting the first step on the same device under test, once or two or more consecutive times; a fifth step for conducting in succession the fourth step on a plurality of devices under test after conducting the third step; and a sixth step for finding the relationship between the total time for which the first voltage has been applied and the current for each device under test, and an apparatus that uses this method.

The current when the total time for which the stress voltage has been applied is short can be measured over a wide range of currents and the malfunction generation time can be estimated from a broad distribution of measurement results that includes the respective measurement result; therefore, reliability testing can be conducted with greater precision than in the past. As a result, high-precision reliability testing is possible while maintaining the basic structure of the apparatus of prior art.

### BRIEF DESCRIPTION OF THE DRAWINGS

FIG. 1 shows a drawing of a conventional reliability testing apparatus.

FIG. 2 is an operation flow chart for a conventional reliability testing apparatus.

FIG. 3 is a timing chart of a conventional reliability testing apparatus.

FIG. 4 is a description of service life estimation by a conventional reliability testing apparatus.

FIG. 5 is an operational flow chart for the reliability testing apparatus of the first embodiment of the present invention.

FIG. 6 is a timing chart of the reliability testing apparatus of the first embodiment of the present invention.

FIG. 7 is a description of service life estimation by the reliability testing apparatus of the first embodiment of the present invention.

FIG. 8 is a sketch of the reliability testing apparatus of the second embodiment of the present invention.

FIG. 9 is an operational flow chart for the reliability testing apparatus of the second embodiment of the present invention.

FIG. 10 is a timing chart of the reliability testing apparatus of the second embodiment of the present invention.

FIG. 11 is a sketch of the reliability testing apparatus of the first embodiment of the present invention.

### DETAILED DESCRIPTION OF THE PREFERRED EMBODIMENT

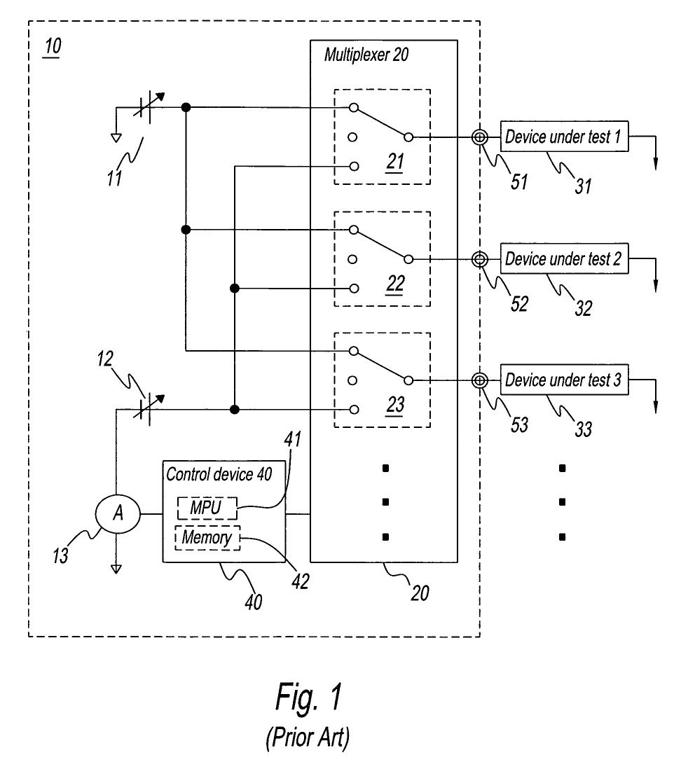

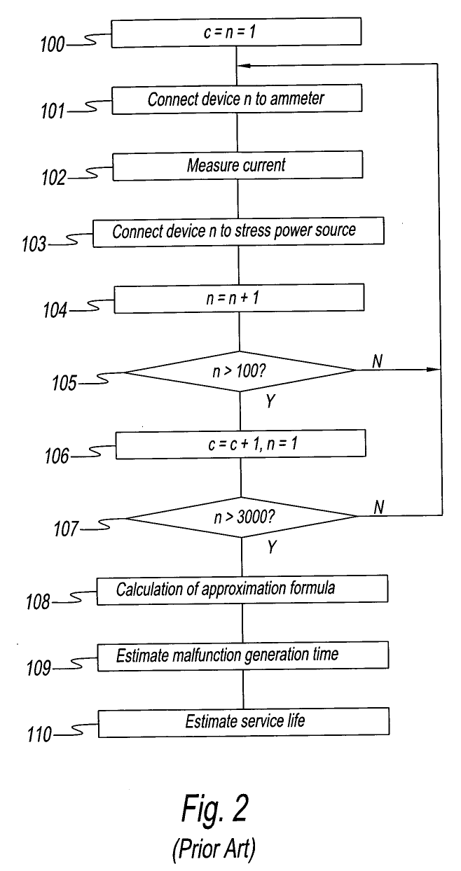

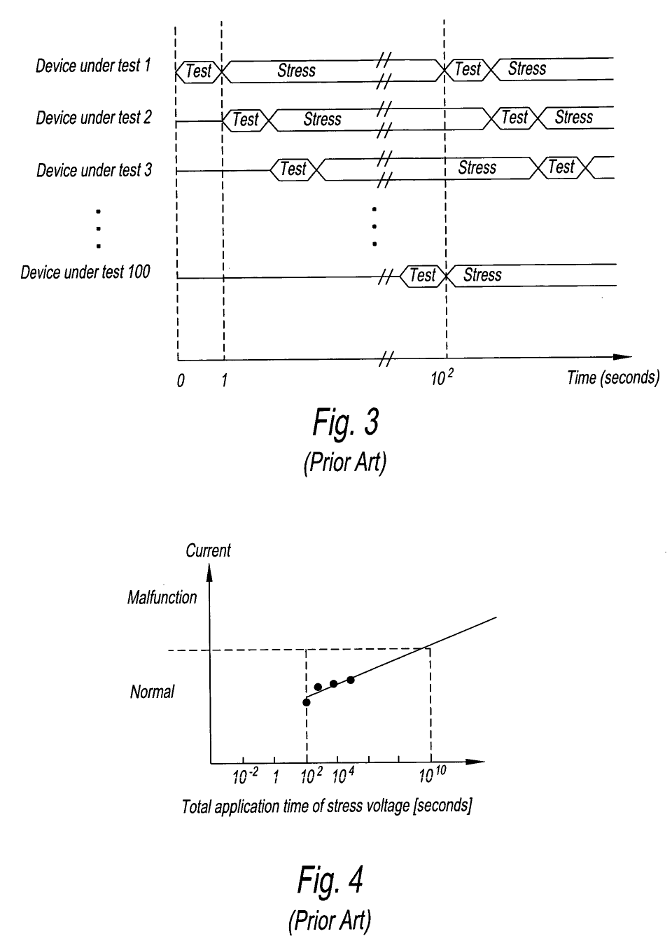

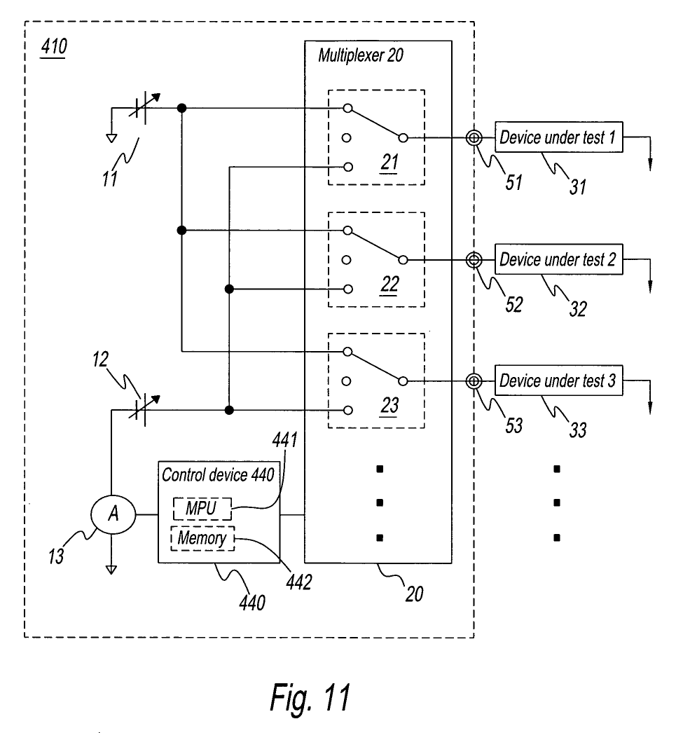

A typical example of the present invention will now be described while referring to the drawings. The structure of an apparatus 10 for reliability testing of the present invention is the same as that of apparatus 410 for reliability testing of the prior art, with the exception that the control method of a control device 40 is different. Therefore, the same symbols are assigned to the hardware in FIG. 1 having the same function as that in FIG. 11. Moreover, the hardware structure of an MPU 41 and a memory 42 housed inside control device 40 is the same as that of MPU 441 and memory 442 of control device 440.

The apparatus for reliability testing 10 of the present invention will now be described with emphasis on the operation of the apparatus for reliability testing.

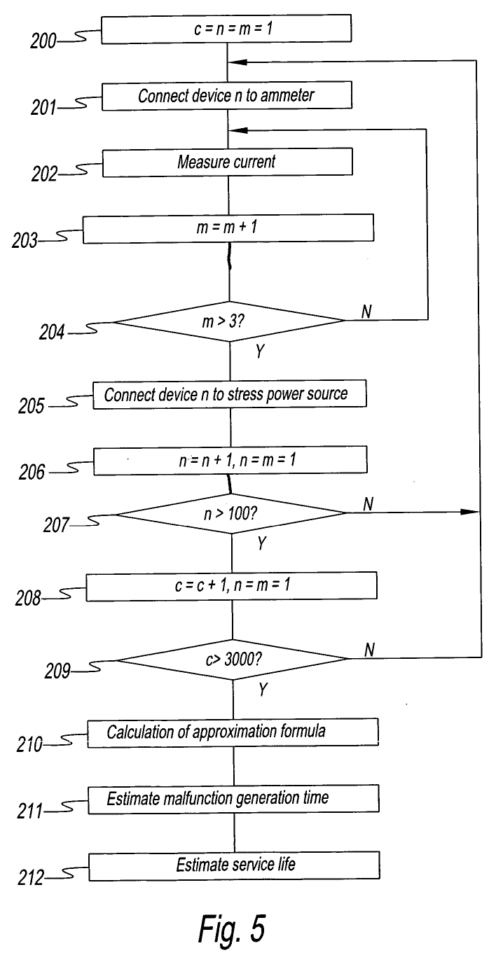

FIG. 5 is the operation flow chart of apparatus 10 for reliability testing of the first embodiment.

First, the user connects 100 devices under test 31, 32, 33, and so forth to the respective connection terminals 51, 52, 53, and so forth. Each of devices under test 31, 32, 33, and so forth is normally used under an applied voltage of 3 V. When connection is completed, the user instructs control device 40 to begin the reliability testing. As a result, control device 40 initializes to 1 a variable c indicating the number of measurements of the device under test; m indicating the number of times the same device has been measured; and variable n indicating the No. of the device currently being measured (step 200). All of switches 21, 22, 23, and so forth of multiplexer 20 are set so that they are not connected to power source 11 or power source 12. Moreover, the output voltages of both power source 11 and power source 12 are set at the stress voltage. In the present example the stress voltage was 10 V, or approximately three-times the applied voltage at which the device is normally used, but it is not necessarily set at this voltage and can be set as needed taking into consideration the device properties, the time needed for the test, and similar considerations.

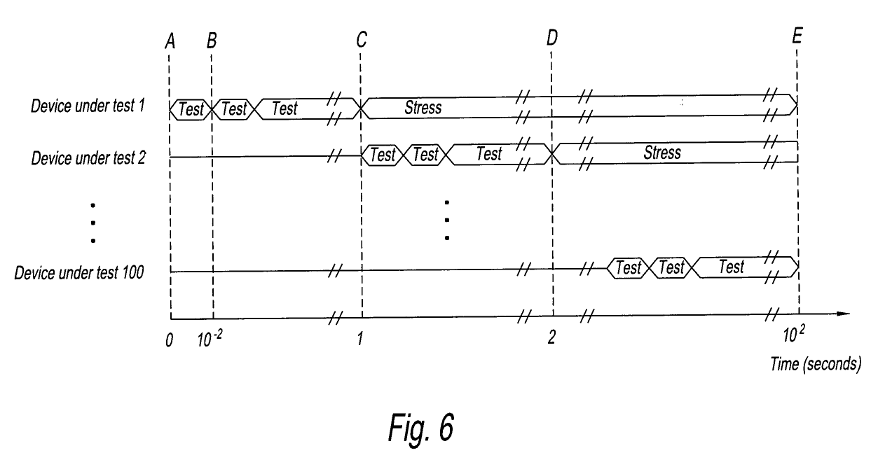

Measurement of the connected device under test is then started. First, control device 40 switches switch 21 of multiplexer 20 and electrically connects the first device 31 to ammeter 13 (step 201). Moreover, the current flowing from power source 12 to device 31 is measured by ammeter 13 and the initial current is stored in memory 42 (step 202, A to B of FIG. 6). Variable m is then increased (step 203) and the same test is performed twice (step 204, B to C of FIG. 6). The switching operation of switch 21 is not performed between the first and second tests or between the second and third tests; therefore, a test can be conducted every 10 ms. That is, three tests provide three pieces of data: the initial current, the current after a total time of 10 ms for which the stress voltage is applied and the current after a total time of 20 ms for which the stress voltage is applied. The measurement results are stored in memory 42 together with the total time.

Next, switch 21 is switched and terminal 51 is connected to power source 11 (step 205). The first set of tests of device 31 is completed (point C in FIG. 6). Moreover, variable n is increased and variable m is initialized to 1 (step 206). Then the first set of tests of the current of the next device under test 32 is started. Switching by switches 21 and 22 is necessary in order to test device 32. Therefore, it takes approximately one second until testing begins. However, as shown in FIG. 6, the stress voltage is not applied to device 32 during the switching operation; therefore, three tests provide three pieces of data for device 32 as well, the initial current, the current after a total time of 10 ms for which the stress voltage is applied, and [the current] after a total time of 20 ms for which the stress voltage is applied (C to D in FIG. 6).

The first set of tests comprising three consecutive tests are similarly conducted in succession on 100 devices (A to E in FIG. 6). Once the first set of tests is completed for all devices (step 207), control device 40 increases variable c and initializes variables m and n to 1 (step 208), and the second set of tests is conducted starting with first device 31. The second set of tests is performed three consecutive times on each device.

The switching operation of switch 21 is necessary in order to switch the device under test; therefore, it takes one second in order to complete one set of tests for each device. Consequently, the time it takes to finish testing all devices is the product of the testing time for one set and the number of devices measured. In the present example, the number of devices tested is 100 and it therefore takes 100 seconds to finish testing each device. The stress voltage is being applied by power source 11 to device 31 as the other devices are being tested. Consequently, the second set of tests measures the current after the total time for which the stress voltage is applied is 100 seconds, 100.01 seconds and 100.02 seconds.

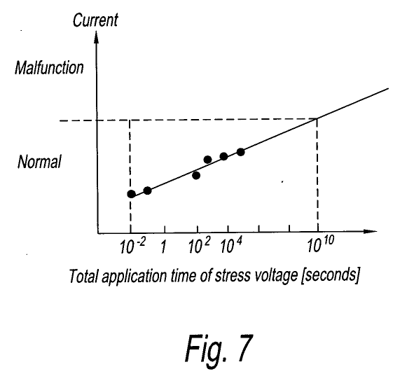

Thus, 3,000 sets of tests are repeated for each device (step 209). Once the tests are completed, control device 40 finds the approximation formula showing the relationship between the total time for which the stress voltage is applied and the current for each device using MPU 41 (step 210). The relationship varies with the type of device, but is generally approximated with a linear function, a higher-order function, an exponential function, and the like, by the least-squares method or another method, with the x-axis serving as the time axis on a logarithmic scale. FIG. 7 shows the relationship between the test results of device under test 31 and the approximation formula. A typical six-point plot is shown in the figure, but a linear approximation formula is actually found by the least-squares method based on the measurement results of 9,000 points.

Next, the time when malfunction occurs is estimated from the resulting approximation formula (step 211). The current that serves as the indicator of a malfunction is pre-specified taking into consideration the extent of breakdown in the gate oxide film; therefore, the total time for which the stress voltage is applied until there is a malfunction (malfunction generation time) is estimated by using the approximation formula to calculate backwards the application time when the current in question is obtained. In the case of device 31, it is estimated that malfunction will occur when the stress voltage is applied for 10¹⁰ seconds, as in FIG. 7. The estimated malfunction generation time is the result of measuring current while applying a stress voltage that is higher than the voltage under which the device is normally used. Therefore, the service life of semiconductor devices 31, 32, 33, and so forth is estimated by conversion to the service life when used under the voltage that is normally used (step 212). The above-mentioned estimation of service life is conducted for each device and the reliability testing is completed.

As is clear when the conventional example in FIG. 4 is compared to the example of the present invention in FIG. 7, it is possible to obtain stable results of estimating service life that are much more precise than with the prior art by the method of the present invention, because the test results are distributed over a broad range of 10⁻² to 10⁵ when the time axis is on a logarithmic scale.

It should be noted that the output voltage of power source 11 and of power source 12 is set at the stress voltage in the above-mentioned examples, but it is not necessary to set the two at the same voltage. For instance, it is possible to test at a voltage that is closer to the voltage normally used by setting the output voltage of power source 11 at the stress voltage and setting the output voltage of power source 12 at a voltage that is within the range applied with normal usage. When conducting steps 202 through 204 of the above-mentioned example in this case, the output voltage of power source 12 [is set] at a voltage that is within the range that is applied during normal usage when measuring the current (for instance, device 31 is set at 3 V) and one set of tests (3) can be performed while repeatedly switching the output voltage such that the voltage is the stress voltage at any time during execution of the “testing” cycle in FIG. 6 other than the measurement operation of ammeter 13 (for instance, writing to memory 42, and the like).

The phrase “the testing step is conducted x number of “consecutive times” of the present invention means that once a predetermined device is tested from among a plurality of devices under test, the same device is retested without testing the other devices. Consequently, cases in which the stress voltage is applied for a predetermined time after measuring the current of a predetermined device with ammeter 13 and then the current of the same device is remeasured using ammeter 13 is included in the concept of “consecutive” tests.

In addition, it is possible to shorten the test time further by changing the number of times a device is tested, such as by testing once per set beginning with the second set (the condition of step 204 is that m>1) when it is not necessary to obtain 3 tests for one set beginning with the second set of measurements. The specific time for one set is determined by the number of tests, which is set by the user, and the control time, such as the switching time of multiplexer 20. Moreover, the total time for which the stress voltage is applied until the second set is initiated is determined by the product of the time needed for one set and the number of devices under test. In short, it is possible to obtain a considerable amount of current data from a short total time of stress voltage application with an increase in the number of times the current is measured in the first set, but the total time for which stress voltage is applied until the second set is initiated will be prolonged. Consequently, the user must set the number of tests taking into consideration the testing points that are needed in order to improve the precision of the relationship and the service life estimates.

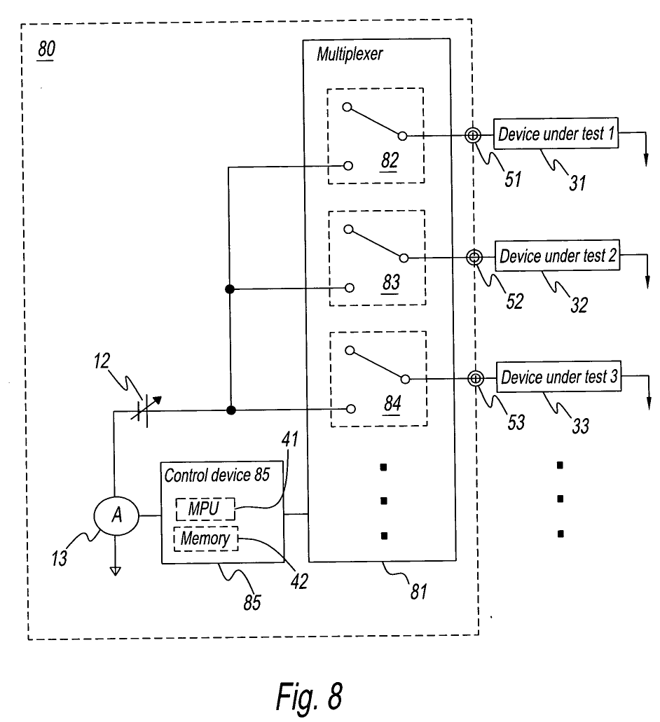

FIG. 8 shows a drawing of an apparatus 80 for reliability testing of a second embodiment of the present invention. There are three differences between the structure of apparatus 80 for reliability testing of the present example and apparatus 10 for reliability testing in FIG. 1: there is no power source 11; therefore, there is only one pole in switches 82, 83, 84, and so forth of a multiplexer 81 (in the figure there is only one set comprised of ammeter and power source and there is therefore a two-pole switch, but when there is a plurality of sets, the number of poles in a switch is the number of sets +1); and the control method of a control device 85 is different. As is clear from the figure, the reliability testing apparatus 80 has a structure wherein reliability testing apparatus 10 has been simplified; therefore, it is possible to conduct reliability testing by the testing method of the present example by using the structure of reliability testing apparatus 10 and changing only the control method of control device 40.

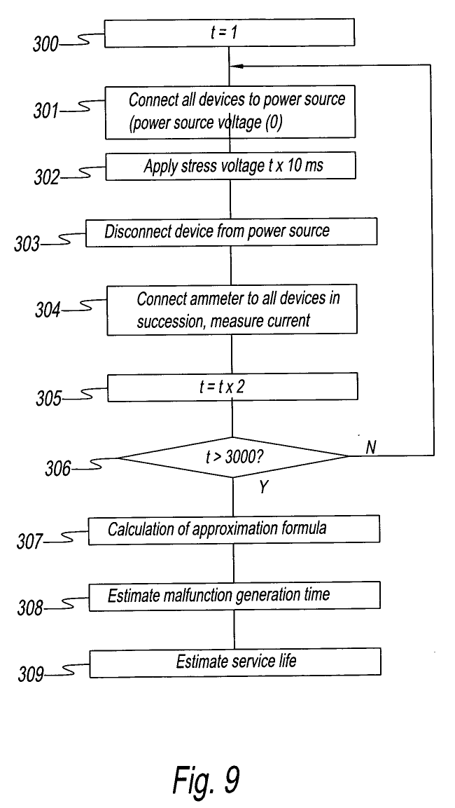

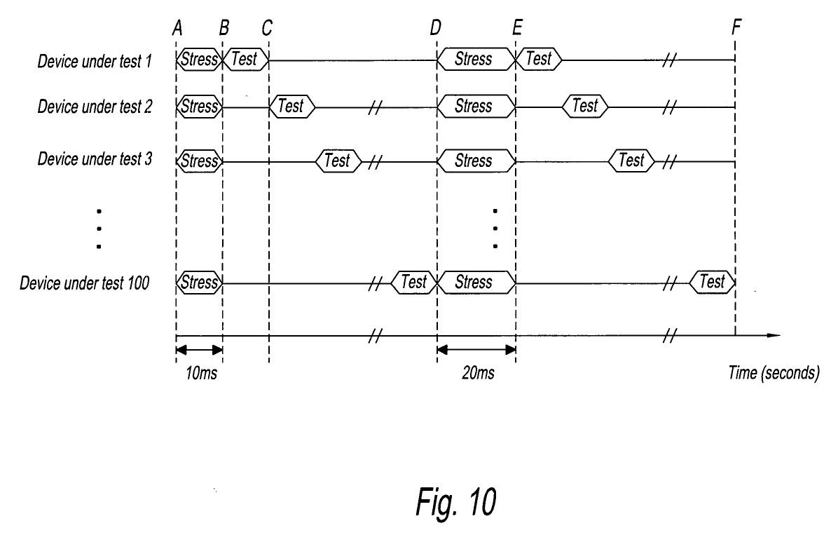

Next, the operation of reliability testing apparatus 80 will be described in detail while referring to the flow chart in FIG. 9 and the timing chart in FIG. 10. The user connects 100 devices under test 31, 32, 33, and so forth to the respective connection terminals 51, 52, 53, and so forth. When the connections are completed, the user instructs control device 85 to start the reliability testing. As a result, control device 85 sets a variable t, which is an indicator of stress voltage application time, to 1 (step 300). It also switches all of switches 82, 83, 84, and so forth of multiplexer 81 to being electrically connected to power source 12 (step 301). The output voltage of power source 12 is 0 at this time.

Control device 85 then applies the output voltage of power source 12 for t×10 ms and applies the stress voltage (10 V) (step 302, A to B in FIG. 10). t=1 initially; therefore, the stress voltage is applied to all devices for 10 ms. Then control device 85 controls multiplexer 81 and switches all switches other than switch 82 (step 303). That is, only device 31 connected to connection terminal 51 is electrically connected to ammeter 13. In this state, the output voltage of power source 12 is set at 3 V, which is a voltage within the range applied with normal usage of device 31, the current flowing through connection terminal 51 is measured by ammeter 13, and the test results are stored in memory 42 together with the total time for which the stress voltage was applied (10 ms) (B to C in FIG. 10). In addition, switch 82 and switch 83 are switched, so that only device 32 connected to connection terminal 52 is electrically connected to ammeter 13, and the measurement of the current and then storage in memory 42 are similarly conducted. Thus, the current when the total time for which the stress voltage is applied is 10 ms is measured for each device (step 304, B to D in FIG. 10).

Next, variable t is doubled (step 305). Moreover, the operation from step 301 to step 305 is repeated until variable t exceeds 3,000 (step 306). That is, by repeating the test a second time, the stress voltage is applied to each device for 20 ms (D to E in FIG. 10), and then the current under a total stress voltage application time of 30 ms is measured for each device (E to F in FIG. 10). By repeating the test a third time, a stress voltage time of 40 ms is applied and data are obtained for a total stress voltage application time of 70 ms.

Once variable t exceeds 3,000, control device 40 finds the formula for the relationship between the total stress voltage application time and the current for each device using MPU 41 (step 307). The relationship varies with the type of device, but it is generally approximated with a linear function, a higher-order function, an exponential function and the like, by the least-squares method or another method, with the x-axis serving as the time axis on the logarithmic scale. Next, the time at which malfunction occurs is estimated from the resulting formula (step 308). The current that is an indicator of malfunction is pre-specified taking into consideration the extent of breakdown of the gate oxide film; therefore it is possible to estimate the stress voltage application time when a malfunction will occur (malfunction generation time) by backward calculation of the application time when the formula gives the current in question. The estimated malfunction generation time is the result of testing while applying a stress voltage that is higher than the voltage normally used; therefore, the result is converted to the time under the conditions normally used and the service life of semiconductor devices 31, 32, 33, and so forth is estimated (step 309). The above-mentioned service life estimation is conducted in succession on each device to complete the reliability testing.

By means of the apparatus and method of the present invention, the stress voltage is not applied to other devices as the current is being measured; therefore, regardless of the number of devices connected to reliability testing apparatus 80, test data are obtained over a broad range of total stress voltage application times. On the other hand, because the stress voltage is intermittently applied, the present invention cannot be used for the reliability testing of devices having a repetitive effect (devices in which the gate oxide film breakdown varies, both when the stress voltage is continuously applied and when it is intermittently applied).

The technological concept of the present invention has been discussed in detail while referring to specific examples. However, it will be clear to persons skilled in the art related to the present invention that various modifications and changes are possible without deviating from the essential points and scope of the claims. For instance, in the second example, the stress voltage application time was a multiple of 10 ms, but the application time can also be set with a shorter time as the time unit when the device has a fast processing speed. Moreover, the examples described service life tests on semiconductor devices as one type of reliability testing, but the present invention can be used for hot carrier testing and other types of reliability testing.

What is claimed is:

1. A method for the reliability testing of a device under test, said method comprising:
a first step for measuring the current flowing to a device under test when a second voltage is applied for a predetermined time after a first voltage has been applied to the device under test;
a second step for conducting the first step on the same device under test 2 or more consecutive times;
a third step for conducting in succession the second step on a plurality of devices under test;
a fourth step for conducting the first step on the same device under test once or two or more consecutive times;
a fifth step for conducting in succession the fourth step on a plurality of devices under test after conducting the third step; and
a sixth step for finding the relationship between the total time for which the first voltage was applied and the current for each device under test.

2. The method for the reliability testing of a device under test according to claim 1, further comprising:
a seventh step for estimating the malfunction generation time when said current reaches a predetermined value from said relationship, and
an eighth step for estimating the service life of the device under test from the malfunction generation time.

3. The method for reliability testing according to claim 1, further comprising a step for application of the first voltage to one of the plurality of devices under test on which the second step has not been conducted when the fifth step is being conducted.

4. A method for reliability testing of a device under test, said method comprising:
a first step for applying for a predetermined time a first voltage to a plurality of devices under test;
a second step for measuring the current flowing through a device under test when a second voltage is successively applied to the plurality of devices under test;
a third step for repeating a predetermined number of times the first step and the second step;
a fourth step for estimating the malfunction generation time when said current reaches a predetermined value from the total time for which the first voltage has been applied and said current for each device under test; and
a fifth step for estimating the service life of the device under test from the estimated malfunction generation time.

5. The method for reliability testing according to claim 4, wherein said first and second voltages are the same voltage.

6. The method for reliability testing according to claim 4, wherein said second voltage is a voltage within the range applied with normal usage of the device under test.

7. A computer-readable recording medium on which a program is recorded thereon for use on a computer, said program comprising: a method for the reliability testing of a device under test, said method comprising:
a first step for measuring the current flowing to a device under test when a second voltage is applied for a predetermined time after a first voltage has been applied to the device under test;
a second step for conducting the first step on the same device under test 2 or more consecutive times;
a third step for conducting in succession the second step on a plurality of devices under test;
a fourth step for conducting the first step on the same device under test once or two or more consecutive times;
a fifth step for conducting in succession the fourth step on a plurality of devices under test after conducting the third step; and
a sixth step for finding the relationship between the total time for which the first voltage was applied and the current for each device under test.

8. A reliability testing apparatus for a device under test that comprises
a first and a second power source;
a plurality of connection terminals for connecting a device under test;
a multiplexer comprising a plurality of switches with a plurality of inputs and one output and wherein the plurality of inputs comprises a first input connected electrically to the first power source, a second input connected electrically to a second power source, and a third input that is not connected to either power source;
an ammeter connected in series to the second power source; and
controller having a memory and data processor,
wherein said controller comprises: a first function for connecting some of the plurality of connection terminals to the second input and connecting the other connection terminals to the third input; a second function for setting the output voltage of the first power source at the stress voltage and setting the output voltage of the second power source at the measurement voltage; a third function for measuring a plurality of consecutive times the current flowing through the connection terminals connected to the second input and after the measurement, connecting the connection terminals connected to the second input to the first input; a fourth function for conducting in succession the third function on the plurality of connection terminals; a fifth function for connecting the plurality of connection terminals in succession to the second function and measuring in succession the current flowing through the connection terminals after conducting the third function;
a sixth function for storing in the memory the current and the total time for which the stress voltage has been applied to the connection terminals that have been measured; a seventh function for estimating the malfunction generation time when said current reaches a predetermined value from the current and the total time stored in the memory; and an eighth function for estimating the service life of the device under test from the estimated malfunction generation time.

9. The method for reliability testing according to claim 8, wherein said measurement voltage and the stress voltage are the same voltage.

10. The method for reliability testing according to claim 8, wherein said measurement voltage has a plurality of voltage levels that include the stress the voltage and the voltage within the range applied with normal usage of the device under test.

11. An apparatus for reliability testing of a device under test comprising:
a power source;
a plurality of connection terminals for connecting the device under test;
a multiplexer with a plurality of switches for controlling the electrical connection between the power source and connection terminals;
an ammeter for in-series connection with the power source; and
controller having a memory and data processor,
wherein said controller comprises: a function for controlling the multiplexer and the power source and applying a first voltage to the plurality of connection terminals; a function for controlling the multiplexer, the ammeter, and the power source, applying a second voltage to some of the connection terminals, and measuring the voltage that flows through the connection terminals; a function for storing in the memory the current and the total time for which the first voltage is applied to the connection terminals that have been measured; a function for estimating the malfunction generation time when the current flowing to the device under test reaches a predetermined value for every device under test from the current and the total time stored in the memory; and a function for estimating the service life of the device under test from the malfunction generation time.

12. The method for reliability testing according to claim 11, wherein said power source can provide output switching between the stress voltage and a voltage within the range applied with normal usage of the device under test.
